(19) United States
(12) Patent Application Publication
(10) Pub. No.: US 2026/0171756 A1
(43) Pub. Date: Jun. 18, 2026

(54) SURFACE EMITTING LASER DEVICE AND MANUFACTURING METHOD THEREOF

(71) Applicant: Hon Hai Precision Industry Co., Ltd., New Taipei City (TW)

(72) Inventors: Yu-Heng HONG, New Taipei City (TW); Hao-Chung KUO, New Taipei City (TW); Hsin-Chieh Yu, New Taipei City (TW); Hui-Tzu Yeh, New Taipei City (TW)

(73) Assignee: Hon Hai Precision Industry Co., Ltd., New Taipei City (TW)

(21) Appl. No.: 19/070,453

(22) Filed: Mar. 4, 2025

(30) Foreign Application Priority Data
Dec. 16, 2024 (TW) 113148872

(51) Int. Cl. H01S 5/183; H01S 5/125

(52) U.S. Cl. CPC H01S 5/18311; H01S 5/125; H01S 2301/166

(57) ABSTRACT

A surface emitting laser device including a first type distributed Bragg reflective layer, an active layer, a second type distributed Bragg reflective layer, and an oxide layer is provided. The active layer is configured on the first type distributed Bragg reflective layer. The second type distributed Bragg reflective layer is configured on the active layer. The oxide layer is configured at a side of the second type distributed Bragg reflective layer adjacent to the active layer. The oxide layer has an opening, and a light emitted by the active layer passes through the opening. A top portion of a local region of the second type distributed Bragg reflective layer has at least one recess and an oxide region. The recess communicates with the oxide region, and the oxide region is located above the opening. A manufacturing method of a surface emitting laser device is also provided.

### CROSS-REFERENCE TO RELATED APPLICATION

This application claims the priority benefit of Taiwan application serial no. 113148872, filed on Dec. 16, 2024. The entirety of the above-mentioned patent application is hereby incorporated by reference herein and made a part of this specification.

### BACKGROUND

### Technical Field

The disclosure relates to a laser and a manufacturing method thereof, and in particular to a surface emitting laser device and a manufacturing method thereof.

### Description of Related Art

Regarding the current manufacturing processes of surface emitting lasers, for example, surface emitting lasers made from gallium arsenide series materials, a high aluminum content oxide layer is typically fabricated above the active layer during the epitaxial process. This provides a current confinement structure (i.e., selective oxide layer) through high-temperature wet oxidation in subsequent processes. The selective oxide layer not only supports a gain waveguide but also provides a refractive index waveguide effect, resulting in better operating characteristics compared to traditional surface emitting lasers made using ion implantation methods.

However, in order to improve the operating characteristics of the device, control the divergence angle of the output light beam, and achieve high-speed modulation, methods are usually employed to enable the surface emitting laser to achieve single transverse mode output. Since the selective oxide layer is typically very close to the gain region of the active layer, to obtain single transverse mode laser output, the current confinement aperture for a surface emitting laser with a light emission wavelength of 850 nanometers generally needs to be smaller than 5 micrometers. For the selective oxidation process, precisely controlling the oxidation aperture to be below 5 micrometers is quite challenging and has low reproducibility.

### SUMMARY

The disclosure provides a surface emitting laser device that achieves single transverse mode output with lower cost, higher yield, and higher reliability.

A manufacturing method for a surface emitting laser device is also provided. The device achieving single transverse mode output with higher reliability may be manufactured using simple, low-cost, and high-yield process steps.

An embodiment of the disclosure presents a surface emitting laser device including a first type distributed Bragg reflective layer, an active layer, a second type distributed Bragg reflective layer, and an oxide layer. The active layer is configured on the first type distributed Bragg reflective layer. The second type distributed Bragg reflective layer is configured on the active layer. The oxide layer is configured at a side of the second type distributed Bragg reflective layer adjacent to the active layer. The oxide layer has an opening, and a light emitted by the active layer passes through the opening. A top portion of a local region of the second type distributed Bragg reflective layer has at least one recess and an oxide region. The at least one recess communicates with the oxide region. The oxide region is located above the opening and causes the second type distributed Bragg reflective layer to have a greater reflectivity in the local region than a reflectivity in a region outside the local region.

An embodiment of the disclosure presents a manufacturing method of a surface emitting laser device. A surface emitting laser chip is provided. The surface emitting laser chip includes a first type distributed Bragg reflective layer, an active layer, a second type distributed Bragg reflective layer, and an oxide layer. The active layer is configured on the first type distributed Bragg reflective layer. The second type distributed Bragg reflective layer is configured on the active layer. The oxide layer is configured at a side of the second type distributed Bragg reflective layer adjacent to the active layer. The oxide layer has an opening for allowing light emitted by the active layer to pass through. At least one recess is etched at a top portion of a local region of the second type distributed Bragg reflective layer. A local oxidation is performed on the second type distributed Bragg reflective layer adjacent to the recess to form an oxide region located above the opening. The oxide region causes the second type distributed Bragg reflective layer to have a greater reflectivity in the local region than a reflectivity in a region outside the local region.

In the surface emitting laser device of the embodiment of the disclosure, the top portion of the second type distributed Bragg reflective layer includes an oxide region. The oxide region is located above the opening and causes the second type distributed Bragg reflective layer to have a greater reflectivity in the local region than a reflectivity in a region outside the local region. Therefore, the surface emitting laser device of the embodiment of the disclosure achieves single transverse mode output through a simple structure while maintaining lower cost and higher yield. Additionally, the oxide region has a stable structure rather than a suspended structure, providing the surface emitting laser device with high reliability. In the manufacturing method for the surface emitting laser device of the embodiment of the disclosure, at least one recess is etched at a top portion of a local region of the second type distributed Bragg reflective layer. A local oxidation is performed on the second type distributed Bragg reflective layer adjacent to the recess to form an oxide region located above the opening. The oxide region causes the second type distributed Bragg reflective layer to have a greater reflectivity in the local region than a reflectivity in a region outside the local region. Therefore, the manufacturing method of the embodiment of the disclosure may use simple, low-cost, and high-yield process steps to produce a surface emitting laser device that achieves single transverse mode output. Moreover, because the oxide region has a stable structure rather than a suspended structure, the manufacturing method of the embodiment of the disclosure produces a surface emitting laser device with high reliability.

### BRIEF DESCRIPTION OF THE DRAWINGS

FIG. 1 is a perspective view of a surface emitting laser device along its optical axis in an embodiment of the disclosure.

FIG. 2 illustrates the relationship between the transverse mode of the laser light and the oxide region in FIG. 1.

FIG. 3 is a perspective view of a surface emitting laser device along its optical axis in another embodiment of the disclosure.

FIG. 4 is a perspective view of a surface emitting laser device along its optical axis in yet another embodiment of the disclosure.

FIGS. 5A and 5B are perspective views along the optical axis showing two steps of the manufacturing method of the surface emitting laser device in an embodiment of the disclosure.

FIG. 6 is a distribution diagram of the E² field intensity and the refractive index relative to the cross-sectional depth of the surface emitting laser chip in FIG. 5A.

FIG. 7 is a distribution diagram of the E² field intensity and the refractive index relative to the cross-sectional depth of the surface emitting laser device in FIG. 1.

### DESCRIPTION OF THE EMBODIMENTS

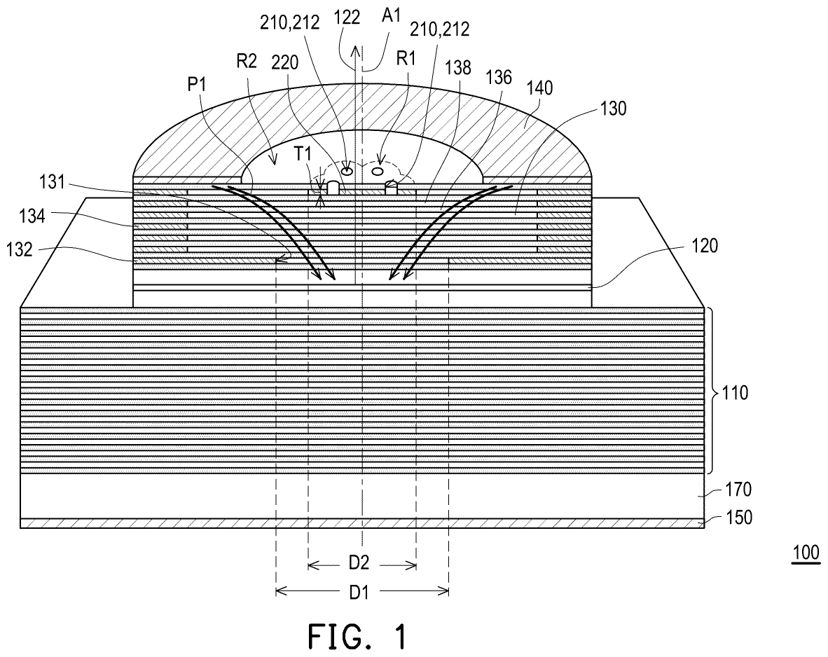

FIG. 1 is a perspective view of a surface emitting laser device along its optical axis in an embodiment of the disclosure. Referring to FIG. 1, a surface emitting laser device 100 of this embodiment includes a first type distributed Bragg reflective layer 110, an active layer 120, a second type distributed Bragg reflective layer 130, and an oxide layer 132. The active layer 120 is configured on the first type distributed Bragg reflective layer 110. The second type distributed Bragg reflective layer 130 is configured on the active layer 120. One of the first type distributed Bragg reflective layer 110 and the second type distributed Bragg reflective layer 130 is an N-type semiconductor layer, and the other one of the first type distributed Bragg reflective layer 110 and the second type distributed Bragg reflective layer 130 is a P-type semiconductor layer. In the example of this embodiment, the first type distributed Bragg reflective layer 110 is the N-type semiconductor layer, and the second type distributed Bragg reflective layer 130 is the P-type semiconductor layer. However, in other embodiments, the first type may be the P-type, and the second type may be the N-type.

The oxide layer 132 is configured at a side of the second type distributed Bragg reflective layer 130 adjacent to the active layer 120. The oxide layer 132 has an opening 131, and light emitted by the active layer 120 passes through the opening 131.

In this embodiment, the first type distributed Bragg reflective layer 110 and the second type distributed Bragg reflective layer 130 are formed by stacking multiple alternating layers of high refractive index films and low refractive index films. The oxide layer 132 is formed through a selective oxidation process applied to the original layers of the second type distributed Bragg reflective layer 130. Specifically, the edges of the second type distributed Bragg reflective layer 130 are exposed to moisture and oxygen, allowing oxygen to diffuse into the layers and oxidize them into the oxide layer 132. In addition to the oxide layer 132, the edges above the oxide layer 132 in the second type distributed Bragg reflective layer 130 are also slightly oxidized, forming an oxide layer 134.

Specifically, the second type distributed Bragg reflective layer 130 includes multiple high refractive index layers 136 and multiple low refractive index layers 138 alternately stacked. The refractive index of the high refractive index layers 136 is greater than that of the low refractive index layers 138. In this embodiment, the high refractive index layers 136 are made of materials such as gallium arsenide, while the low refractive index layers 138 are made of materials such as aluminum gallium arsenide. The low refractive index layers 138 have a high aluminum content. Therefore, when the low refractive index layers 138 come into contact with moisture and oxygen, their material is easily converted from aluminum gallium arsenide to aluminum oxide, forming the oxide layers 132 and 134.

The top portion of the local region R1 (e.g., the central region) of the second type distributed Bragg reflective layer 130 has at least one recess 210 and an oxide region 220. In this embodiment, the at least one recess 210 is multiple blind holes 212 dispersedly arranged in an annular pattern. The recess 210 communicates with the oxide region 220, and the oxide region 220 is located above the opening 131. The oxide region 220 causes the second type distributed Bragg reflective layer 130 in the local region R1 to have a greater reflectivity than in the region R2 outside the local region R1. This results in the local region R1 achieving single transverse mode output of a laser light 122 from the active layer 120, while the region R2 outside the local region R1 suppresses the laser light 122 with multiple transverse modes from the active layer 120.

Specifically, the oxide region 220 is in the same layer as at least one low refractive index layer 138 at the top portion of the second type distributed Bragg reflective layer 130. In this embodiment, the oxide region 220 may be a single layer formed by oxidizing one low refractive index layer 138 at the top portion of the second type distributed Bragg reflective layer 130. Additionally, in this embodiment, a thickness T1 of each layer of the oxide region 220 in the same layer as the at least one low refractive index layer 138, multiplied by the refractive index of the oxide region 220, equals one-quarter of the wavelength of the laser light 122 from the active layer 120. As a result, in the region R2, which is in the same layer as the oxide region 220 but where the low refractive index layer 138 is not oxidized, the product of the refractive index and the thickness T1 does not equal one-quarter of the wavelength of the laser light 122. This results in poor reflectivity in region R2, suppressing the formation of high-order transverse modes of the laser light 122. Conversely, when at least one low refractive index layer 138 in the top portion of the local region R1 is oxidized into the oxide region 220, the refractive index is reduced, making the product of the refractive index and the thickness T1 equal to one-quarter of the wavelength of the laser light 122. This increases the reflectivity in the local region R1. Since the position of the local region R1 corresponds to the position of the fundamental mode of the laser light 122, its high reflectivity enables the laser light 122 to achieve single transverse mode output.

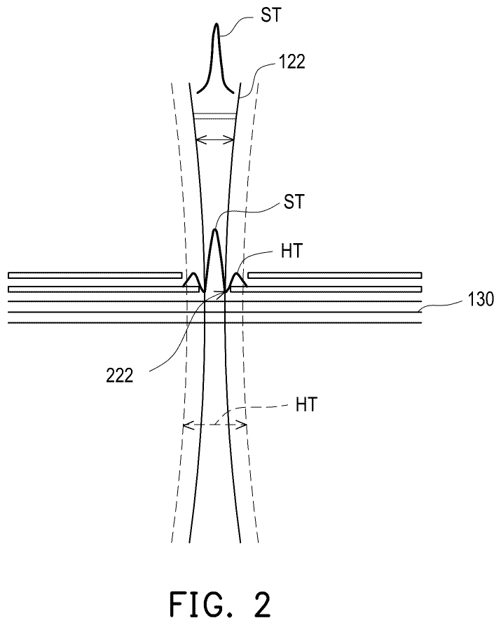

FIG. 2 illustrates the relationship between the transverse mode of the laser light and the oxide region in FIG. 1. Referring to FIG. 1 and FIG. 2, the oxide region 220 may be regarded as the light-emitting aperture 222 of the laser light 122. As shown in FIG. 2, the position outside the light-emitting aperture 222 corresponds to the position of a high-order transverse mode HT of the laser light generated by the active layer 120, while the light-emitting aperture 222 corresponds to a position of the single transverse mode ST. Therefore, the high-order transverse mode HT is suppressed, and the laser light 122 with the single transverse mode ST is output through the light-emitting aperture 222. This allows the surface emitting laser device 100 in this embodiment to achieve single transverse mode output.

In the surface emitting laser device 100 of this embodiment, the top portion of the second type distributed Bragg reflective layer 130 includes an oxide region 220 located above the opening 131. The oxide region 220 causes the second type distributed Bragg reflective layer 130 in the local region R1 to have a greater reflectivity than in the region R2 outside the local region R1. This enables the local region R1 to achieve single transverse mode output of the laser light 122 from the active layer 120, while the region R2 outside the local region R1 suppresses the laser light 122 with multiple transverse modes from the active layer 120. Therefore, the surface emitting laser device 100 of this embodiment achieves single transverse mode output through a simple structure, while maintaining lower cost and higher yield. Additionally, the oxide region 220 has a stable structure, rather than a suspended structure, providing the surface emitting laser device 100 of this embodiment with high reliability.

In this embodiment, the diameter D1 of the opening 131 ranges from 5 micrometers to 10 micrometers. In this embodiment, the oxide region 220 is used to form a region that allows the single transverse mode laser light 122 to pass through, and suppresses high-order transverse modes in the region R2 outside this area, instead of relying solely on the opening 131 to suppress high-order transverse modes. As a result, the size of the opening 131 formed by the selective oxidation process does not need to be highly precise or very small (e.g., less than 5 micrometers), significantly improving the yield of the selective oxidation process. Furthermore, compared to the distance between the opening 131 and the active layer 120, the distance between the oxide region 220 and the active layer 120 is greater. This means the beam waist of the laser light 122 generated by the active layer 120 is farther away at the position of the oxide region 220, where the beam has already expanded. Consequently, the diameter D2 of the oxide region 220 does not need to be very small (e.g., less than 5 micrometers) to correspond to the position of the single transverse mode. This effectively improves the process yield of forming the oxide region 220. In one embodiment, the diameter D2 of the oxide region 220 is approximately 5 micrometers to 10 micrometers. In this embodiment, the oxide region 220 intersects an optical axis A1 of the surface emitting laser device 100, meaning the oxide region 220 exists at the optical axis A1. Additionally, the oxide region 220 is formed continuously in the area surrounded by the recess 210.

In this embodiment, the surface emitting laser device 100 further includes an upper electrode 140, which is configured in a surrounding region at the top portion of the second type distributed Bragg reflective layer 130. Furthermore, the surface emitting laser device 100 includes a lower electrode 150, which is configured below the first type distributed Bragg reflective layer 110. A substrate 170 may be disposed between the first type distributed Bragg reflective layer 110 and the lower electrode 150. When a forward voltage is applied between the upper electrode 140 and the lower electrode 150, the active layer 120 emits light. This light is reflected back and forth between the first type distributed Bragg reflective layer 110 and the second type distributed Bragg reflective layer 130, undergoing resonance, and eventually generates the laser light 122. The laser light 122 partially penetrates the second type distributed Bragg reflective layer 130 and is transmitted to the external environment.

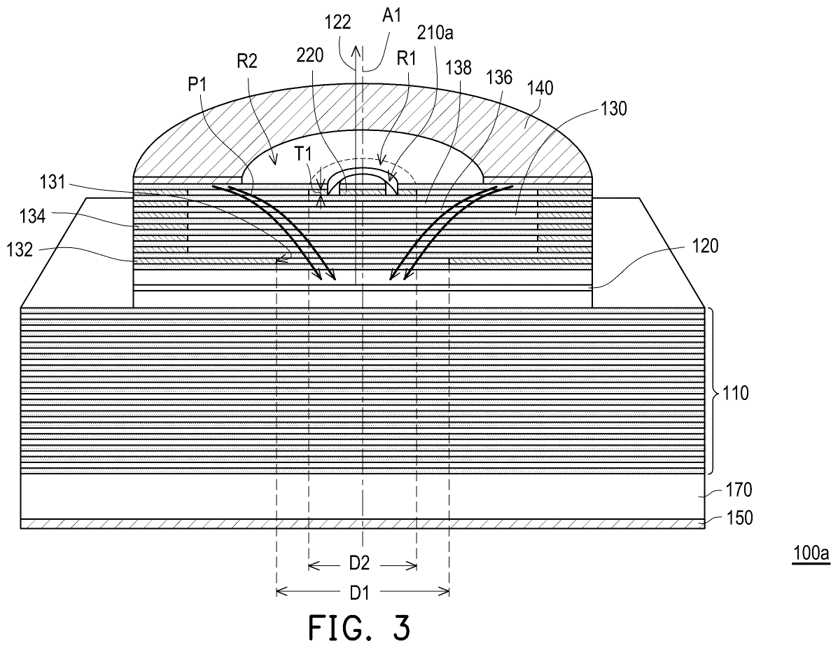

FIG. 3 is a perspective view of another embodiment of the surface emitting laser device along its optical axis. Referring to FIG. 3, a surface emitting laser device 100a in this embodiment is similar to the surface emitting laser device 100 in FIG. 1. The difference between them is that, in this embodiment, a recess 210a is a continuous annular groove extending to form a complete circle.

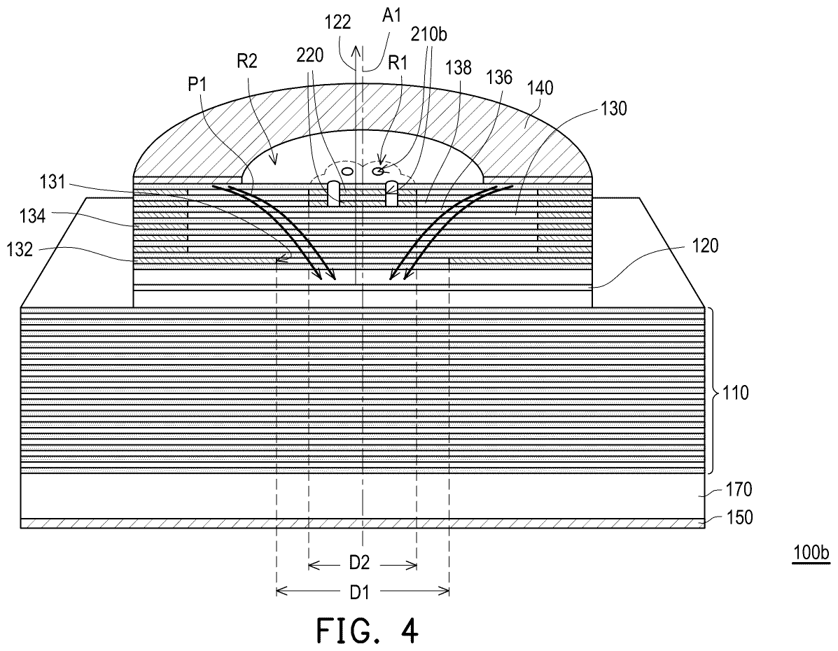

FIG. 4 is a perspective view of yet another embodiment of the surface emitting laser device along its optical axis. Referring to FIG. 4, a surface emitting laser device 100b in this embodiment is similar to the surface emitting laser device 100 in FIG. 1. The difference between them lies in that, in FIG. 1, the recess 210 communicates with a single oxide region 220 formed by locally oxidizing one low refractive index layer 138, whereas in FIG. 4, a recess 210b communicates with multiple oxide regions 220 formed by locally oxidizing multiple low refractive index layers 138. (In FIG. 4, two oxide regions 220 are shown as an example, but in other embodiments, there may be three or more oxide regions 220.)

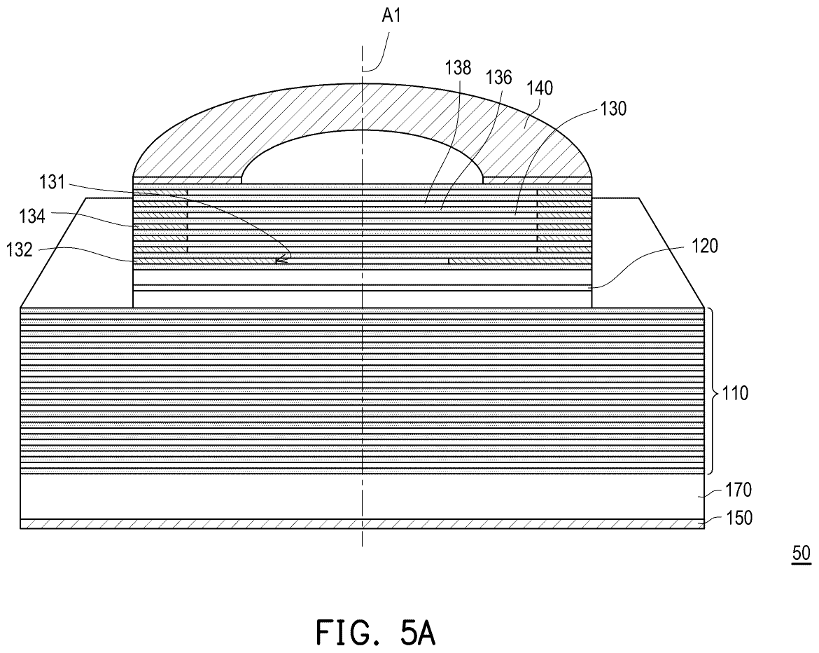

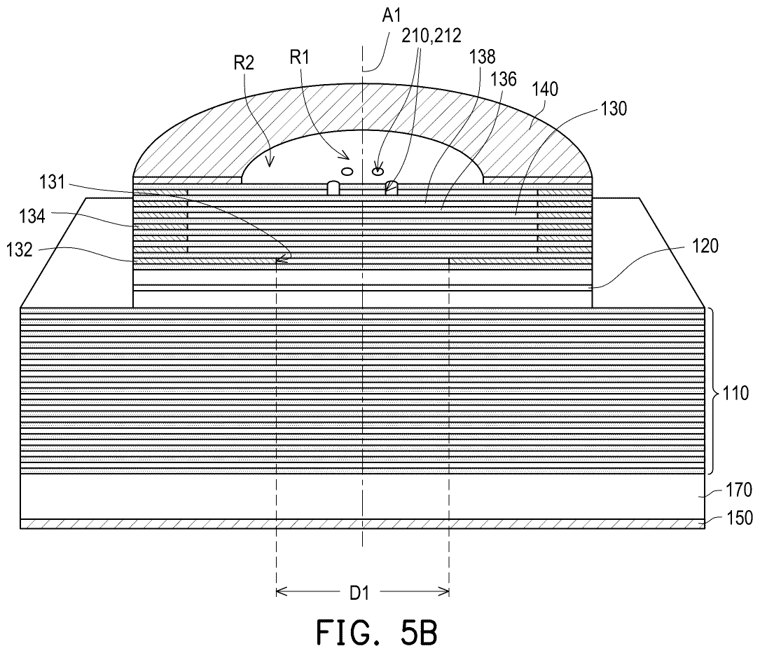

FIGS. 5A and 5B are perspective views along the optical axis showing two steps in the manufacturing method for a surface emitting laser device in an embodiment of the disclosure. Referring to FIG. 1, FIG. 5A, and FIG. 5B, the manufacturing method of the surface emitting laser device in this embodiment may be used to fabricate the surface emitting laser devices 100, 100a, or 100b in the described embodiments. The following description uses the fabrication of the surface emitting laser device 100 in FIG. 1 as an example. The manufacturing method for the surface emitting laser device in this embodiment includes the following steps. First, as shown in FIG. 5A, a surface emitting laser chip 50 is provided. The surface emitting laser chip 50 includes a first type distributed Bragg reflective layer 110, an active layer 120, a second type distributed Bragg reflective layer 130, and an oxide layer 132. The active layer 120 is configured on the first type distributed Bragg reflective layer 110. The second type distributed Bragg reflective layer 130 is configured on the active layer 120. The oxide layer 132 is configured at a side of the second type distributed Bragg reflective layer 130 adjacent to the active layer 120. The oxide layer 132 has an opening 131 for allowing light emitted by the active layer 120 to pass through. Next, as shown in FIG. 5B, at least one recess 210 is etched on the top portion of the local region R1 of the second type distributed Bragg reflective layer 130. For example, the recess 210 may be etched using a lithographic process or other suitable methods. The etching process may be dry etching, wet etching, or performed using focused ion beams or ultrashort pulse lasers to form the recess 210. Then, as shown in FIG. 1, a local oxidation is performed on the second type distributed Bragg reflective layer 130 adjacent to the recess 210 to form an oxide region 220 above the opening 131. The oxide region 220 causes the second type distributed Bragg reflective layer 130 in the local region R1 to have a greater reflectivity than in the region R2 outside the local region R1. This enables the local region R1 to achieve single transverse mode output of the laser light 122 from the active layer 120, while the region R2 outside the local region R1 suppresses the laser light 122 with multiple transverse modes from the active layer 120.

Specifically, in this embodiment, the step of performing local oxidation on the second type distributed Bragg reflective layer 130 adjacent to the recess 210 includes performing local oxidation on at least one low refractive index layer 138 adjacent to the recess 210 to form the oxide region 220. For example, moisture and oxygen may be introduced into the recess 210, allowing oxygen to diffuse into the low refractive index layer 138 and transform the aluminum gallium arsenide material of the low refractive index layer 138 into aluminum oxide, thereby forming the oxide region 220. In this way, the surface emitting laser device 100 may be fabricated. The optical axis of the surface emitting laser chip 50 is also the optical axis A1 of the surface emitting laser device 100, and the oxide region 220 intersects the optical axis A1.

Furthermore, the detailed structure of the surface emitting laser device 100 or other embodiments such as the surface emitting laser devices 100a and 100b fabricated by the manufacturing method of this embodiment is as described in the embodiments shown in FIGS. 1 to 4, and will not be repeated here.

In the surface emitting laser devices 100, 100a, and 100b described in the above embodiments and the manufacturing method of the surface emitting laser device in this embodiment, in the surface emitting laser structure made of the gallium arsenide/aluminum gallium arsenide material system, the desired low refractive index layer 138 is exposed through dry etching or wet etching. Then, using selective oxidation technology, a hybrid distributed Bragg reflector (i.e., the second type distributed Bragg reflective layer 130) composed of dielectric oxide material (i.e., the material of the oxide region 220) and semiconductor material is fabricated. The following features are achieved:
1. Since the refractive index difference between the oxide region 220 and the high refractive index layer 136 is greater than the refractive index difference between the low refractive index layer 138 and the high refractive index layer 136, a high reflectivity may be achieved with fewer layers. Therefore, the number of layers in the second type distributed Bragg reflector may be reduced by approximately one-third, shortening the epitaxial growth time and lowering the cost.
2. The area of the oxide region 220 may be easily controlled by adjusting the etched recess 210.
3. Single transverse mode output may be achieved by adjusting the area of the oxide region 220, without requiring the selective oxidation process to precisely control the diameter of the opening 131 to less than 5 micrometers or even smaller.

The method described in this embodiment avoids the processing difficulties and high resistance associated with high refractive index contrast gratings or solely etched photonic crystal methods. In this embodiment, the current from the upper electrode 140 flows to the active layer 120 along a path P1 with minimal obstruction. Additionally, the entire device does not have a suspended structure as seen in the high refractive index contrast grating method. Therefore, there is no need for supercritical carbon dioxide cleaning equipment, and there is no risk of fragile suspended structures collapsing under pressure.

In one embodiment, a vertical-cavity surface-emitting laser at 940 nm made of gallium arsenide/aluminum gallium arsenide is used as an example. For traditional surface emitting lasers made of gallium arsenide series materials at wavelengths of 850 nm, 940 nm, or 980 nm, a single selective oxidation technique is typically used as a current confinement method. To achieve a reflectivity of 99%, more than 50 pairs of gallium arsenide/aluminum gallium arsenide distributed Bragg reflectors are usually required. For the high-reflectivity surface (corresponding to the first type distributed Bragg reflective layer 110), more than 30 pairs are typically needed. For the emission side mirror (corresponding to the second type distributed Bragg reflective layer 130), which requires a lower reflectivity, around 25 pairs are still necessary. The dual oxidation-confined structure proposed in this embodiment retains the complete bottom N-type doped gallium arsenide/aluminum gallium arsenide distributed Bragg reflectors (i.e., the first type distributed Bragg reflective layer 110) and the active layer 120 as its core structure. The difference lies in the top P-type distributed Bragg reflectors (i.e., the second type distributed Bragg reflective layer 130), which require only 8 pairs to be grown. Compared to conventional gallium arsenide-based surface emitting lasers, this embodiment reduces the required number of grown pairs to about one-third.

Without increasing the number of reflector layers (i.e., the second type distributed Bragg reflective layer 130), the reflectivity of the top Bragg reflector (i.e., the second type distributed Bragg reflective layer 130) is effectively enhanced by selectively oxidizing the topmost high-aluminum-content aluminum gallium arsenide layer, converting the layer into aluminum oxide (i.e., forming the oxide region 220). The refractive index of this layer is reduced from approximately n=3 to n=1.55. As a result, the refractive index difference between the aluminum oxide and the heavily doped P-type gallium arsenide conductive layer (i.e., the high refractive index layer 136) increases from the original Δn=0.5 to Δn=1.5. Using the Formula (1) below, it may be seen that the reflectivity R is significantly improved. In this formula, R represents the effective reflectivity, μ₂ and μ₃ are the refractive indices of the alternating epitaxial layers, and μ₁ and μₗ represent the refractive indices of the incident and transmission media, respectively. The value N denotes the number of periodic layers.

$$R = [ \frac{1 - \frac{{μ}_{l}}{{μ}_{1}} {( \frac{{μ}_{2}}{{μ}_{3}} )}^{2 N}}{1 + \frac{{μ}_{l}}{{μ}_{1}} {( \frac{{μ}_{2}}{{μ}_{3}} )}^{2 N}} ] \qquad Formula ( 1 )$$

From Formula (1), it may be seen that if the periodic number N of the distributed Bragg reflector is fixed, the smaller the ratio μ₂/μ₃, meaning the greater the refractive index difference, the closer the reflectivity approaches 1. Therefore, by selecting materials with a higher refractive index difference, fewer periods of the distributed Bragg reflective layer may be grown while achieving the desired high reflectivity. Using materials with a larger refractive index difference enables higher reflectivity with fewer reflector pairs. To maintain the thickness of the high-aluminum-content aluminum gallium arsenide layer (i.e., the low refractive index layer 138) after oxidation at one-quarter wavelength, as required by the distributed Bragg reflector, its thickness must be increased from the original approximately 60 nanometers (using an 850 nm surface emitting laser as an example) to 137 nanometers. This relationship is shown in Formula (2):

$$\frac{1}{4} λ = n \times d \qquad Formula ( 2 )$$

Where n is the refractive index, d is the epitaxial layer thickness (e.g., thickness T1), and Δ is the wavelength of the laser light 122.

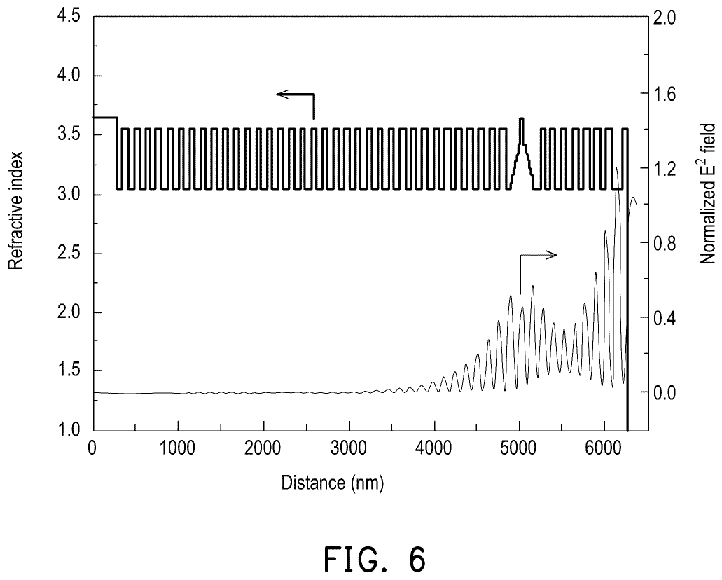

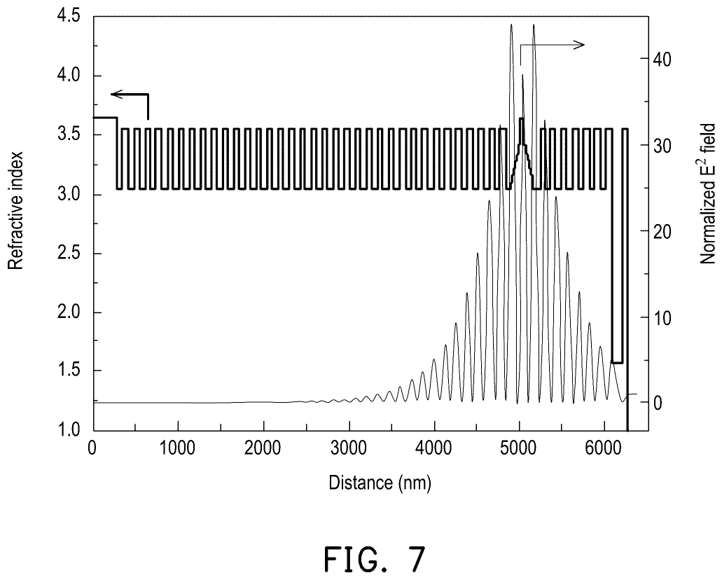

FIG. 6 shows the distribution of the E² field intensity and refractive index relative to the cross-sectional depth of the surface emitting laser chip in FIG. 5A, and FIG. 7 shows the distribution of the E² field intensity and refractive index relative to the cross-sectional depth of the surface emitting laser device in FIG. 1. Referring first to FIG. 5A and FIG. 6, for the surface emitting laser chip 50 without the recess 210 and the oxide region 220, the refractive index distribution and the standing wave distribution of the electric field intensity along the cross-sectional depth are as shown in FIG. 6. In FIG. 6 and FIG. 7, E² represents the square of the absolute value of the electric field, which indicates the intensity of the electric field. The horizontal axis represents the distance from the bottom of the surface emitting laser chip 50 or the surface emitting laser device 100 in the depth direction. Additionally, in FIG. 6 and FIG. 7, the normalized E² field intensity curve corresponds to the scale on the right axis (as indicated by the arrow pointing to the right), while the refractive index curve corresponds to the scale on the left axis (as indicated by the arrow pointing to the left). From FIG. 6, it may be observed that when the thickness of the high-aluminum-content aluminum gallium arsenide layer (i.e., the low refractive index layer 138) in the topmost pair of distributed Bragg reflectors is increased from 60 nanometers to 137 nanometers, its periodicity is disrupted. Consequently, the standing wave distribution of the electric field intensity is no longer consistent with the well-designed surface emitting laser structure. As a result, the active layer 120 is almost unable to achieve effective gain, and the overall structure fails to provide effective optical field confinement. Under these conditions, the structure requires a critical gain as high as approximately 26,600 cm⁻¹ to achieve laser operation, making it almost impossible to achieve laser output under normal operating currents. The refractive index profile of the epitaxial structure and the standing wave distribution of the electric field intensity for this case are shown in FIG. 6.

In contrast, referring again to FIG. 1 and FIG. 7, after the selective oxidation process, the topmost high-aluminum-content aluminum gallium arsenide layer (i.e., the low refractive index layer 138) is transformed into aluminum oxide, reducing its refractive index from 3 to 1.55. The optical equivalent thickness is restored to one-quarter of the design wavelength. As a result, the periodicity of the entire distributed Bragg reflector (i.e., the second type distributed Bragg reflective layer 130) is reinstated. More importantly, the refractive index difference of the topmost pair of Bragg reflectors increases threefold, from the original Δn=0.5 to Δn=1.5. This significantly improves the reflectivity, reducing the critical gain required for laser operation to approximately 590 cm⁻¹, which is 45 times lower than before oxidation. Furthermore, the critical gain is about four times lower than that of typical surface emitting laser structures with eight pairs of top Bragg reflectors. The cross-sectional structure and standing wave distribution of the electric field intensity after oxidation are shown in FIG. 7.

In one embodiment, the first type distributed Bragg reflective layer 110 is, for example, a structure formed by alternating N-type gallium arsenide layers and aluminum gallium arsenide layers. The active layer 120 is, for example, a multi-quantum well layer formed by alternating indium gallium arsenide layers and gallium arsenide layers, or a multi-quantum well layer formed by alternating gallium arsenide layers and aluminum gallium arsenide layers. The second type distributed Bragg reflective layer 130 is, for example, a structure formed by alternating P-type gallium arsenide layers and aluminum gallium arsenide layers. The material of the oxide layer 132 is, for example, aluminum oxide. The material of the oxide layer 134 is also, for example, aluminum oxide. The material of the oxide region 220 is, for example, aluminum oxide. The material of the upper electrode 140 is, for example, titanium, platinum, and gold stacked sequentially from the side close to the second type distributed Bragg reflective layer 130 to the side farther away from the second type distributed Bragg reflective layer 130. Alternatively, the upper electrode 140 may be made of a gold-zinc alloy. The material of the lower electrode 150 is, for example, nickel, gold, and gold-germanium alloy stacked sequentially from the side close to the substrate 170 to the side farther away from the substrate. Alternatively, the lower electrode 150 may be made of a gold-zinc alloy. The material of the substrate 170 is, for example, N-type gallium arsenide. However, the disclosure is not limited to these examples.

In summary, in the surface emitting laser device of the embodiment of the disclosure, the top portion of the second type distributed Bragg reflective layer includes an oxide region located above the opening. The oxide region causes the second type distributed Bragg reflective layer in the local region to have a greater reflectivity than in the region outside the local region. This enables the local region to achieve single transverse mode output of the laser light from the active layer, while the region outside the local region suppresses laser light with multiple transverse modes from the active layer. Therefore, the surface emitting laser device of the embodiment of the disclosure achieves single transverse mode output through a simple structure while maintaining lower cost and higher yield. Additionally, the oxide region has a stable structure rather than a suspended structure, providing the surface emitting laser device of this embodiment with high reliability. In the manufacturing method for the surface emitting laser device of the embodiment of the disclosure, at least one recess is etched at the top portion of the local region of the second type distributed Bragg reflective layer. A local oxidation is performed on the second type distributed Bragg reflective layer adjacent to the recess to form an oxide region located above the opening. The oxide region causes the second type distributed Bragg reflective layer in the local region to have a greater reflectivity than in the region outside the local region. This enables the local region to achieve single transverse mode output of the laser light from the active layer, while the region outside the local region suppresses laser light with multiple transverse modes from the active layer. Therefore, the manufacturing method of the surface emitting laser device in the embodiment of the disclosure may use simple, low-cost, and high-yield process steps to produce a surface emitting laser device that achieves single transverse mode output. Furthermore, because the oxide region has a stable structure rather than a suspended structure, the manufacturing method of the embodiment of the disclosure produces a surface emitting laser device with high reliability.

What is claimed is:

1. A surface emitting laser device, comprising:
a first type distributed Bragg reflective layer;
an active layer, configured on the first type distributed Bragg reflective layer;
a second type distributed Bragg reflective layer, configured on the active layer; and
an oxide layer, configured at a side of the second type distributed Bragg reflective layer adjacent to the active layer, wherein the oxide layer has an opening, and a light emitted by the active layer passes through the opening;
wherein a top portion of a local region of the second type distributed Bragg reflective layer has at least one recess and an oxide region, the least one recess communicates with the oxide region, the oxide region is located above the opening, and the oxide region causes the second type distributed Bragg reflective layer to have a greater reflectivity in the local region than a reflectivity in a region outside the local region.

2. The surface emitting laser device according to claim 1, wherein the at least one recess is a plurality of blind holes dispersedly arranged in an annular pattern.

3. The surface emitting laser device according to claim 1, wherein the at least one recess is an annular groove extending continuously to form a circle.

4. The surface emitting laser device according to claim 1, wherein a diameter of the opening is between 5 micrometers to 10 micrometers.

5. The surface emitting laser device according to claim 1, wherein one of the first type distributed Bragg reflective layer and the second type distributed Bragg reflective layer is an N-type semiconductor layer, and the other one of the first type distributed Bragg reflective layer and the second type distributed Bragg reflective layer is a P-type semiconductor layer.

6. The surface emitting laser device according to claim 1, further comprising an upper electrode, configured in a surrounding region of the top portion of the second type distributed Bragg reflective layer.

7. The surface emitting laser device according to claim 1, wherein the oxide region intersects an optical axis of the surface emitting laser device.

8. The surface emitting laser device according to claim 1, wherein the second type distributed Bragg reflective layer comprises a plurality of high refractive index layers and a plurality of low refractive index layers alternately stacked, wherein a refractive index of the plurality of high refractive index layers is greater than a refractive index of the plurality of low refractive index layers, and the oxide region is in a same layer as at least one of the plurality of low refractive index layers at the top portion of the second type distributed Bragg reflective layer.

9. The surface emitting laser device according to claim 8, wherein a thickness of each layer of the oxide region in the same layer as the at least one low refractive index layer multiplied by a refractive index of the oxide region is equal to one-quarter of a wavelength of a laser light from the active layer.

10. The surface emitting laser device according to claim 1, wherein the oxide region causes the local region to achieve a single transverse mode output of a laser light from the active layer, and causes the region outside the local region to suppress the laser light from the active layer having a plurality of transverse modes.

11. A manufacturing method of a surface emitting laser device, comprising:
providing a surface emitting laser chip, wherein the surface emitting laser chip comprises a first type distributed Bragg reflective layer, an active layer, a second type distributed Bragg reflective layer, and an oxide layer, the active layer being configured on the first type distributed Bragg reflective layer, the second type distributed Bragg reflective layer being configured on the active layer, the oxide layer being configured at a side of the second type distributed Bragg reflective layer adjacent to the active layer, and the oxide layer having an opening for letting a light emitted by the active layer pass through;
etching at least one recess at a top portion of a local region of the second type distributed Bragg reflective layer; and
performing a local oxidation on the second type distributed Bragg reflective layer adjacent to the at least one recess to form an oxide region located above the opening; wherein
the oxide region causes the second type distributed Bragg reflective layer to have a greater reflectivity in the local region than a reflectivity in a region outside the local region.

12. The manufacturing method of the surface emitting laser device according to claim 11, wherein the second type distributed Bragg reflective layer comprises a plurality of high refractive index layers and a plurality of low refractive index layers alternately stacked, wherein a refractive index of the plurality of high refractive index layers is greater than a refractive index of the plurality of low refractive index layers, and performing the local oxidation on the second type distributed Bragg reflective layer adjacent to the recess comprises performing the local oxidation on at least one of the plurality of low refractive index layers adjacent to the recess to form the oxide region.

13. The manufacturing method of the surface emitting laser device according to claim 12, wherein a thickness of each layer of the oxide region formed by the local oxidation of the at least one of the plurality of low refractive index layers multiplied by a refractive index of the oxide region is equal to one-quarter of a wavelength of a laser light from the active layer.

14. The manufacturing method of the surface emitting laser device according to claim 11, wherein the at least one recess is a plurality of blind holes dispersedly arranged in an annular pattern.

15. The manufacturing method of the surface emitting laser device according to claim 11, wherein the at least one recess is an annular groove extending continuously to form a circle.

16. The manufacturing method of the surface emitting laser device according to claim 11, wherein a diameter of the opening is between 5 micrometers to 10 micrometers.

17. The manufacturing method of the surface emitting laser device according to claim 11, wherein one of the first type distributed Bragg reflective layer and the second type distributed Bragg reflective layer is an N-type semiconductor layer, and the other one of the first type distributed Bragg reflective layer and the second type distributed Bragg reflective layer is a P-type semiconductor layer.

18. The manufacturing method of the surface emitting laser device according to claim 11, wherein the oxide region intersects an optical axis of the surface emitting laser device.

19. The manufacturing method of the surface emitting laser device according to claim 11, wherein the surface emitting laser chip further comprises an upper electrode, configured in a surrounding region of a top portion of the second type distributed Bragg reflective layer.

20. The manufacturing method of the surface emitting laser device according to claim 11, wherein the oxide region causes the local region to achieve a single transverse mode output of a laser light from the active layer and causes the region outside the local region to suppress the laser light from the active layer having a plurality of transverse modes.
